(19) United States
(12) Patent Application Publication
(10) Pub. No.: US 2011/0019363 A1
(43) Pub. Date: Jan. 27, 2011

(54) FIELD SERVICEABLE DISPLAY DEVICE

(76) Inventors: Scott Vahlsing, Beaverton, OR (US); Bruce James Sandmeyer, Portland, OR (US); Robert Timothy Flegal, Beaverton, OR (US); Allen Gard, Portland, OR (US); Patrick J. Green, Beaverton, OR (US)

Correspondence Address: STOEL RIVES LLP - PDX, 900 SW FIFTH AVENUE, SUITE 2600, PORTLAND, OR, 97204-1268, US

(21) Appl. No.: 12/842,781

(22) Filed: Jul. 23, 2010

Related U.S. Application Data
(60) Provisional application No. 61/228,155, filed on Jul. 23, 2009.
(60) Provisional application No. 61/357,927, filed on Jun. 23, 2010.

(51) Int. Cl. H05K 7/20

(52) U.S. Cl. 361/695

(57) ABSTRACT

An electronic display panel is ruggedized by optically bonding optically transparent plates to the front and back of the display panel. Electronic devices associated with the display panel, such as drivers, may be encased in a resin or other material to provide environmental and mechanical protection for the electronic devices. An outdoor display device includes a two part housing with a weatherized electronic display panel mounted in one part and a back light mounted in the second part. The housing is easily opened at the display device location to provide access to the back light components and the back of the weatherized electronic display panel for maintenance or other purposes. Fans and air passages may be provided to circulate air through the housing to help cool the display device.

### RELATED APPLICATIONS

This application claims priority under 35 U.S.C. §119(e) to U.S. Patent App. Nos. 61/228,155 titled “Field Serviceable Display Device” and filed on Jul. 23, 2009, and 61/357,927 titled “Field Serviceable Display Device” and filed on Jun. 23, 2010, which are both fully incorporated by reference herein

### TECHNICAL FIELD

The field of the present disclosure relates to ruggedized electronic displays and display systems, and to displays and display systems for outdoor use.

### BACKGROUND

Electronic displays, such as liquid crystal displays, have become less expensive, fueling increased demand for using electronic displays in place of static displays such as sign boards, light boards, and posters, for both indoor and outdoor applications. Capabilities and options available through electronic displays that can be programmed to show images, including text and video, are increasingly in demand for outdoor applications. However, many current electronic displays, including liquid crystal displays, are not suitable for outdoor use.

The present inventors have recognized several challenges associated with adopting electronic displays, such as displays using active matrix liquid crystal display (“AMLCD”) panels, for outdoor use. They recognized that using electronics outdoors places the electronics in a more challenging environment compared to indoor use. Outdoor displays encounter water, particulate matter, insects, temperature variations (both high and low), and brighter ambient light conditions than displays used indoors. They have also recognized that polarizer layers used in liquid crystal displays turn brown when exposed to humidity, thus reducing the brightness of such displays. And, they have recognized that moisture adversely affects the electronics associated with liquid crystal displays. Another recognition is that the sun adversely impacts liquid crystal displays by overheating such displays and potentially causing such displays to clear by heating the liquid crystal to a point where it transitions from its operative nematic phase to an istropic phase that prevents the liquid crystal from properly operating.

The present inventors have recognized that cold cathode fluorescent lamps (“CCFL”), commonly used to backlight AMLCD displays, are typically rated for a 50,000 hour half-life, and that an outdoor display rated at 1000 nits (cd/m²) will likely only have 500 nits available in 5 years, thus making the display unreadable, especially in relatively high levels of ambient light. They have also recognized that films placed between an AMLCD panel and the backlights will yellow over time because of the ultra-violet radiation emitted from CCFLs, and that such yellowing reduces the reflectance of such films and reduces the overall brightness of the AMLCD. They have also recognized that the high voltage of CCFLs attracts dirt and dust into a backlight cavity, and that such dirt and dust becomes entrapped in the middle of the backlight films thus making the backlight cavity difficult to clean. Backlight cavities are commonly sealed to prevent dust from entering the cavity. The present inventors have recognized that such sealed backlight cavities make it difficult to remove heat that builds up in the backlight cavity.

The present inventors have also recognized the uncontrolled outdoor environment commonly leads to placing a display panel and its associated electronics in a “weather-proof” or sealed housing in an attempt to isolate the electronics from environmental conditions. They have recognized that the bright ambient light conditions commonly leads to a need for brighter displays that can be viewed in the bright ambient light, and that brighter AMLCD displays commonly use brighter lamps which often generate significant amounts of heat. They have recognized the combination of weather-proof housings and brighter lamps creates cooling difficulties because the heat from the lamps and from the environment becomes trapped in such weather-proof housings and it is difficult to circulate air through such housings because of their sealed or “weatherized” designs. They also recognized that such cooling problems commonly require heat sinks to be incorporated into a display, adding bulk, weight, and cost to the display.

The present inventors have also recognized that electronic displays used in outdoor environments are likely to be continuously used and therefore powered on for longer periods of time than similar displays used indoors. Because of the increased power on periods, lamps in outdoor displays are more likely to burn out and need to be replaced. They have recognized that weather-proof housings, as well as housings used for indoor applications, are difficult to open and even when open are commonly not designed for relatively easy lamp replacement. Another recognition is that because backlights on large format displays are not easily replaced in the field, such displays are commonly shipped back to a depot for repair, which increases maintenance costs, downtime, and risk of damage. The present inventors have also recognized that dirt and lamp aging will reduce contrast and make a display unreadable in relatively bright ambient light, which, while not a hard failure of any component, compels shipping a display back to a depot for cleaning and lamp replacement.

### SUMMARY

In light of the above problems recognized by the present inventors, they created a ruggedized, or weatherized, display panel for outdoor use that protects the display panel from environmental conditions. In one embodiment, an AMLCD panel is sealed between optically bonded optically transparent plates on the front and back of the AMLCD panel. Optically bonding optically transparent plates to the front and back of the AMLCD panel preferably protects the polarizers from the environment such that they resist browning.

A weatherized AMLCD panel is contained in a display housing that is easily opened. In one embodiment the AMLCD module is moved out of the way to permit relatively easy access to the internal components, such as the lamps, contained in the display housing. Alternately, the backlight module may be moved out of the way to permit relatively easy access to the internal components. Such access allows the backlight cavity to be cleaned, other components to be cleaned, and the lamps to be replaced in the field. The lamps are preferably hot cathode fluorescent lamps (“HCFL”), which are relatively inexpensive and easy to maintain compared to cold cathode fluorescent lamps. Serviceability ease, and access to internal components, is facilitated by creating a display device that contains a weatherized, or ruggedized, AMLCD panel in one module and the backlight in a separate module. The AMLCD display and display housing created by the present inventors address at least some of the above problems, and may address other problems, such as a need for active cooling from devices such as thermoelectric coolers or compressed fluid refrigeration units, associated with using an electronic display outdoors.

Additional aspects and advantages will be apparent from the following detailed description of preferred embodiments, which proceeds with reference to the accompanying drawings.

### BRIEF DESCRIPTION OF THE DRAWINGS

FIG. 1 is a front view of a display device.

FIG. 2 is a left-side isometric view of the display device of FIG. 1.

FIG. 3 is an enlarged left-side section view of the display of FIG. 1.

FIG. 4A is an enlarged top section view of the display of FIG. 1.

FIG. 4B is an enlarged top section view of an alternate embodiment.

FIG. 5 is a front view of a display panel showing row and column driver electronics exposed.

FIG. 6 is an isometric view of a display panel contained in a prior art backlight housing.

FIG. 7 is an enlarged left-side section view of the display of FIG. 1.

FIG. 8 is a section view of the display of FIG. 1 taken along line C-C of FIG. 1.

FIG. 8A is a right-side rear perspective view of an alternate display device in an open condition.

FIG. 9 is a section view of the display of FIG. 1 taken along line A-A of FIG. 1.

FIG. 9A is a section view of an alternate display device.

FIG. 10 is a top sectional schematic view of an alternate display device.

### DETAILED DESCRIPTION OF PREFERRED EMBODIMENTS

While the following discussion references a preferred embodiment having a specific housing structure and using an AMLCD panel, the invention is not limited to the particular details discussed. The invention is defined by the claims in this application.

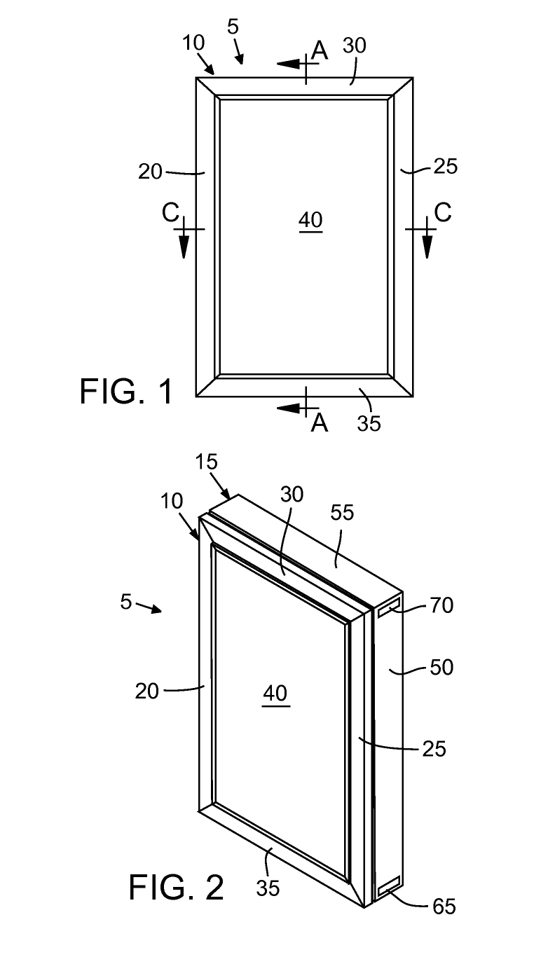

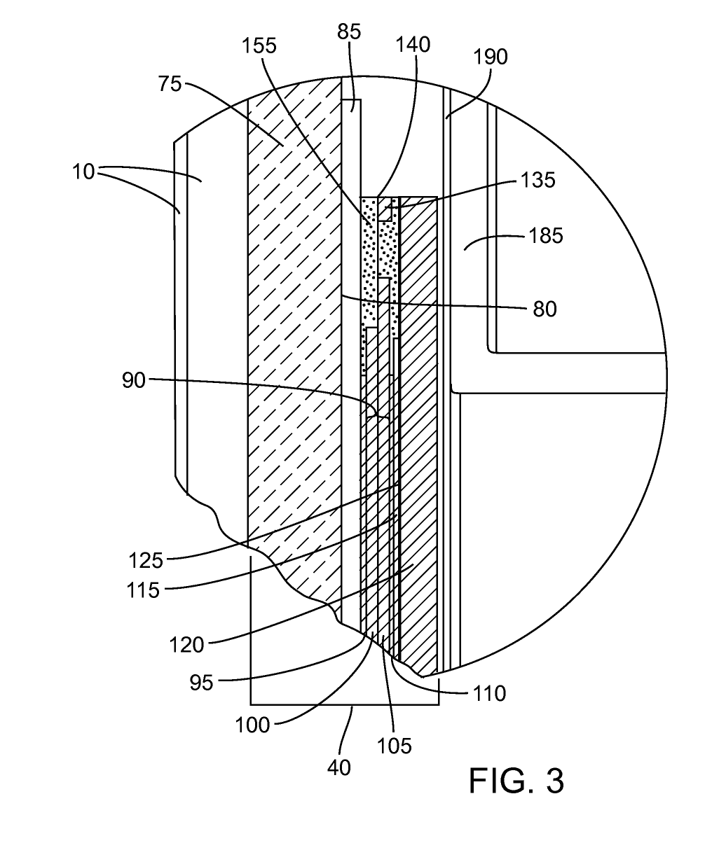

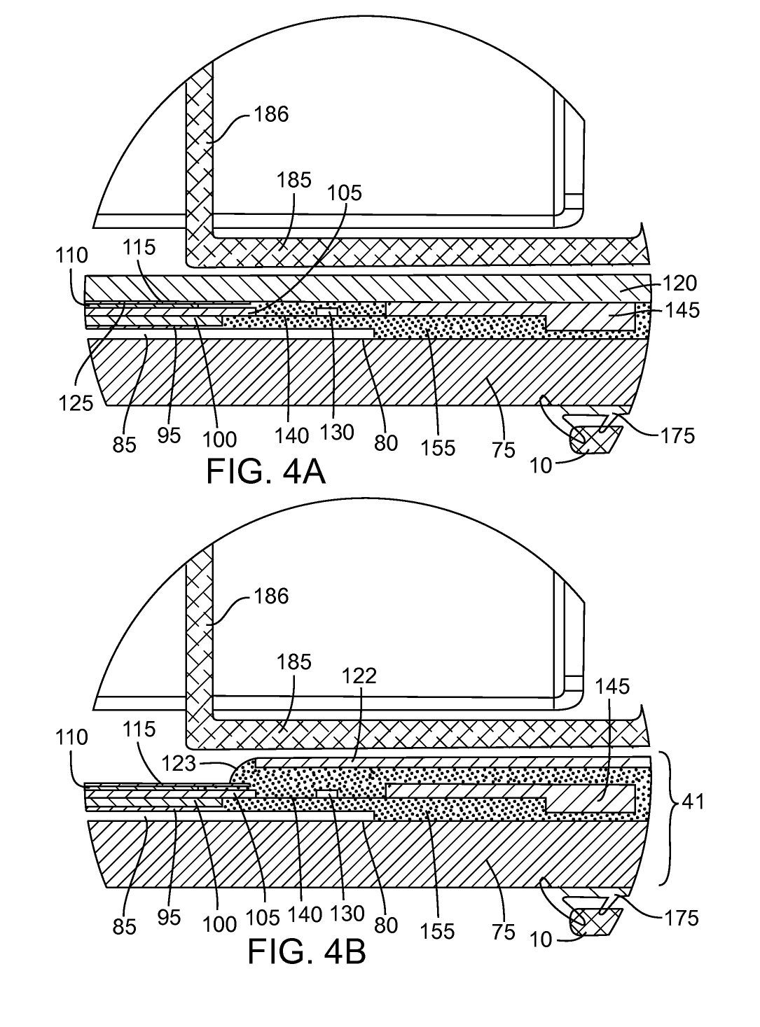

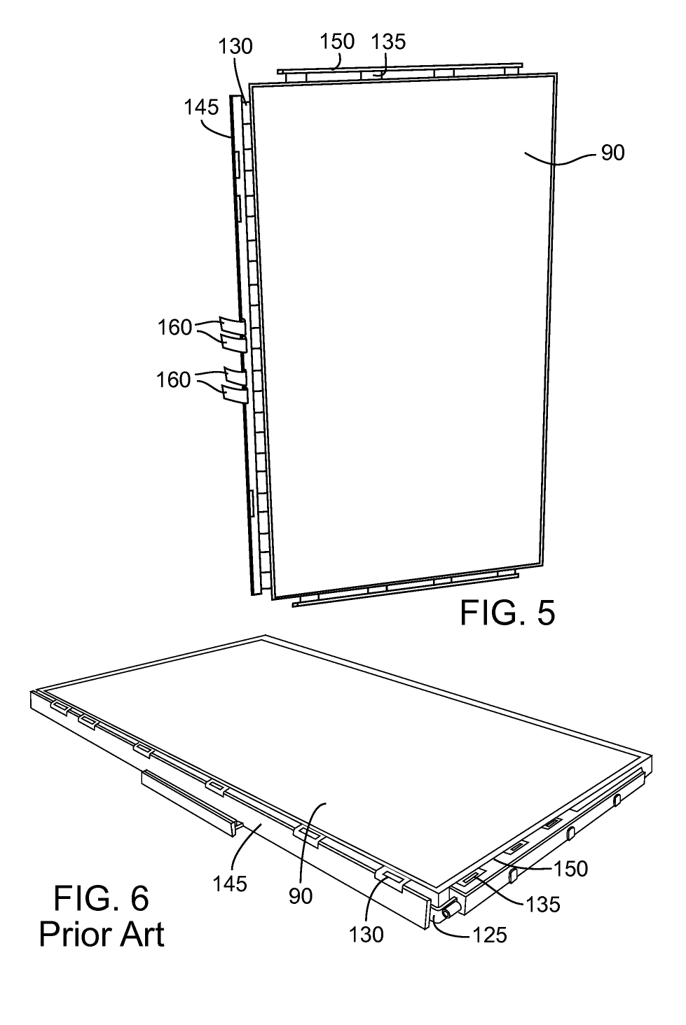

In a particular embodiment illustrated in FIG. 3, an AMLCD panel 90 is optically bonded between a front optically transparent plate 75 and a rear optically transparent plate 120. Optically bonding the AMLCD panel between two optically transparent plates 75, 120 provides protection from the environment for the AMLCD panel 90. Preferably, other layers such as polarizers 95 and 110 are also protected from the environment by the optically bonded optically transparent plates 75 and 120. Certain of the electronics associated with the AMLCD panel, such as row and column drivers 135 and 130 (FIGS. 3 and 4A) and a timing controller board (not illustrated), are preferably also encased in a bonding material 155, or other suitable material, between the optically transparent plates 75, 120. Encasing such electronics preferably seals the electronics from the outside environment and creates a mechanical attachment between the plates 75, 120 and the electronics to provide stability for the electronics. Advantageously, the optically transparent plates and bonding material 155 may protect the AMLCD panel so that the outside of the display device 5 (FIG. 1) can be cleaned by hosing down the display device 5 with water and the inside of the display device 5 can be cleaned by opening the housing 10, 15 (FIG. 2) to wipe down the back side of the AMLCD panel and the backlight cavity.

The front optically transparent plate 75 lies between the AMLCD panel 90 and the outside environment. An infra-red (“IR”) reflecting and visible light transmissive material 80 is preferably included on the front optically transparent plate 75 to reduce the amount of IR radiation (principally greater than 700 nanometers (“nm”)) that reaches the AMLCD panel 90. Reducing the amount of IR radiation that reaches the AMLCD panel 90 helps prevent environmental heating of the AMLCD panel 90.

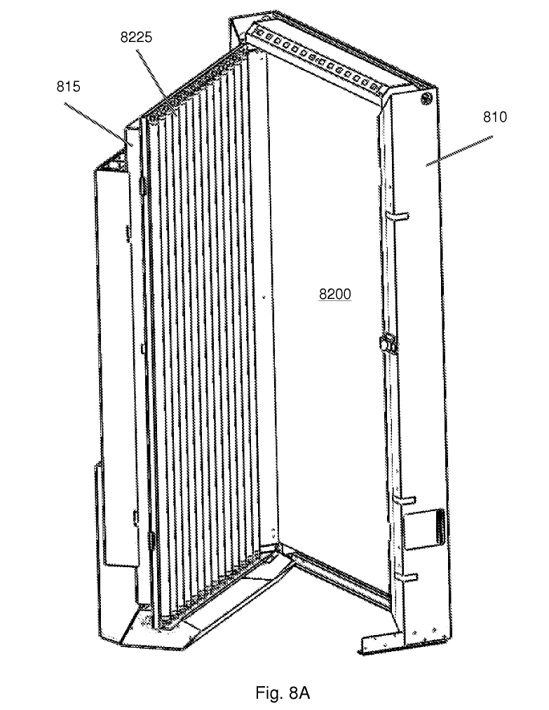

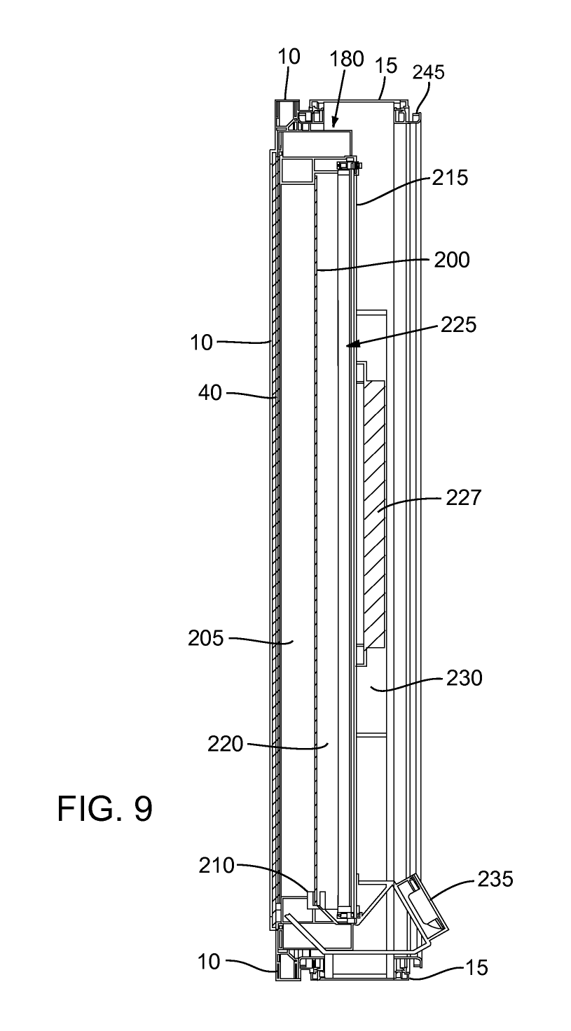

The AMLCD panel 90 is secured in a panel housing 10 (FIG. 7) along with a diffuser 200 (FIG. 7), which evens-out the light generated by a backlight that reaches the AMLCD panel 90 to help reduce or eliminate bright spots viewable on the display 5. The diffuser 200 is spaced apart from the AMLCD panel 90 to create a first airspace 205, which preferably serves as an air flow path (FIG. 8) between the diffuser 200 and the AMLCD panel 90. Because the backlight cavity can be easily cleaned, there is less concern with dust getting in the backlight cavity and fans 235 (FIG. 8) are preferably used to exchange air from within the display housing 10, 15 with air from outside the display housing 10, 15 to cool the inside of the display housing 10, 15 to ambient, or near ambient, temperatures. When ambient temperatures are at or below 0° Celsius, heaters may be provided at or near the air inlet 65 (FIG. 1), or may be provided on the AMLCD itself to permit the lamps 225 (FIG. 8) and AMLCD panel 90 to start up.

The backlight is secured in a backlight housing 15 that is openably connected to the panel housing 10 to provide access to the lamps 225 when opened or detached from the panel housing 10. When the backlight housing 15 is connected to the panel housing 10, lamps 225 of the backlight are spaced apart from the diffuser 200 to create a second airspace 220, which preferably serves as an air flow path (FIG. 8) between the diffuser 200 and the backlight. The diffuser 200 is located between the AMLCD panel 90 and the backlight when the backlight housing 15 is connected to the panel housing 10.

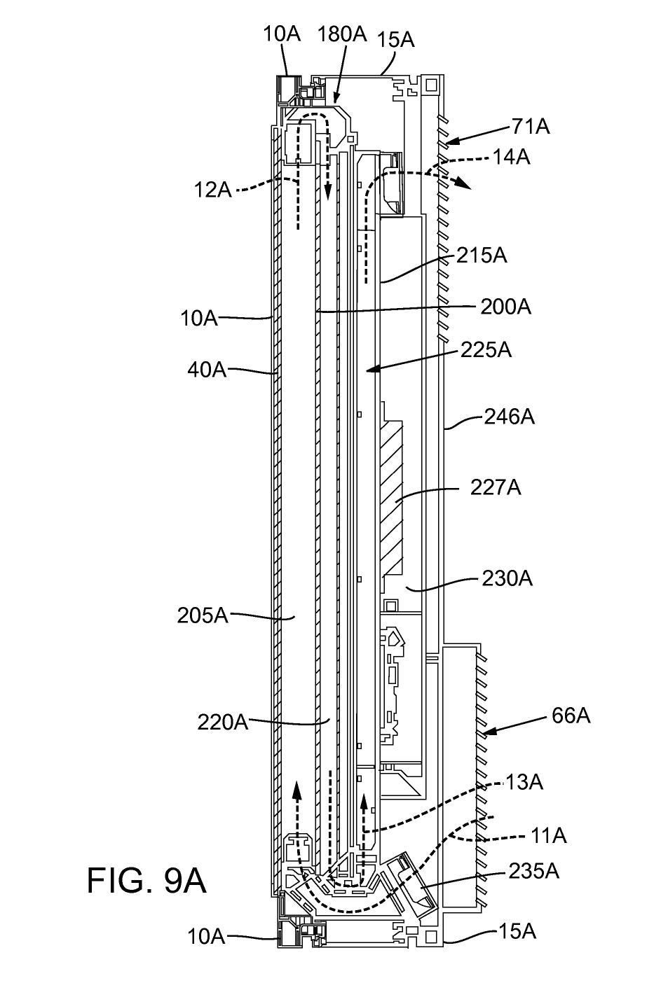

The lamps 225 of the backlight are preferably hot cathode fluorescent lamps (“HCFL”) which require a ballast 227 (FIG. 9) to control the amount of electricity supplied to the lamps 225. In alternate embodiments, backlights may include light emitting diodes or other suitable light emitting elements. The ballast 227 generates heat, and is preferably located behind the lamps 225 in a third airspace 230, which preferably serves as an air flow path (FIG. 9) in the backlight housing 15. Other electronics associated with the display device 5, such as a video driver (not illustrated), are also preferably located in the third airspace 230, or alternately, remote from the display device 5. Dividing the panel housing 10 and the backlight housing 15 into separate airspaces 205, 220, and 230 that contain different components of the display device 5 helps thermally separate the various display components and preferably provides separated cooling air flows blown or moved by fans 235 located at the bottom of the backlight housing 15.

### A Preferred Embodiment

FIGS. 1 and 2 illustrate an assembled display device 5 that includes a panel housing 10 and a backlight housing 15. Preferably, the combination of panel housing 10 connected to backlight housing 15 creates a housing that is weather resistant, but not necessarily weather-proof, in other words, relatively small amounts of moisture, dust, and other environmental elements may enter and exit the housing. The backlight housing 15 is openably connected to the panel housing 10, preferably by an internal hinge 17(FIG. 8), external hinge, or other suitable mechanical connector to provide access to lamps (225 FIG. 8) for replacement and cleaning. However, a mechanical connector is not necessary, and the connection of the backlight housing 15 to the panel housing 10 may include completely physically separating the backlight housing 15 from the panel housing 10. One or more mechanical latches (not illustrated) preferably hold the panel housing 10 and backlight housing 15 in a connected condition and are preferably lockable. One such mechanical latch preferably carries or incorporates an electric disconnect switch (not illustrated), such as an electrical interlock, for example, arranged to cut power to the display device 5 when the mechanical latch is opened or operated to detach the panel housing 10 from the backlight housing 15 to gain access to the internal components of the display device 5 for cleaning, maintenance, or replacement.

In a preferred embodiment, the panel housing 10 includes a right-side frame 20, left-side frame 25, top frame 30, and a bottom frame 35 that cooperatively grip a ruggedized display panel 40, which preferably includes a transmissive image display panel such as an AMLCD panel. Details of the ruggedized display panel 40 are described below. The right-side frame 20, left-side frame 25, top frame 30, and bottom frame 35 are preferably cut at 45-degree angles and fit together similar to a window frame. The right-side frame 20, left-side frame 25, top frame 30, and bottom frame 35 are preferably held together by mechanical fasteners (not illustrated) such as screws or other suitable fasteners, or may be glued, welded, or otherwise suitably bonded together. The right-side frame 20, left-side frame 25, top frame 30, and bottom frame 35 are preferably extruded aluminum, and include a protective coating, such as a powder coating or anodization, to help prevent the aluminum from breaking down due to exposure to outdoor elements.

In a similar manner, the backlight housing 15 preferably includes a right-side frame (not illustrated), left-side frame 50, top frame 55, and bottom frame (not illustrated) made from extruded aluminum and having a protective coating. Backlight housing 15 is preferably assembled similar to panel housing 10. The right-side frame and left-side frame 50 include air intake openings 65 and air outlet openings 70. Air intake openings 65 preferably include a filter material (not illustrated) such as a fine screen mesh or other suitable material for hindering particulate matter, such as dust, and insects from entering backlight housing 15 through air intake openings 65 but allowing air to pass therethrough. In alternate embodiments, air inlets may be solely through a fan system, such as fans 235 (FIG. 8), or may include both a fan system and openings in the housing 10, 15. Air outlet openings 70 are preferably configured to include a protective structure that substantially prevents water and other liquids from entering air outlet openings 70, for example, by including one or more louvers (not illustrated), a slanted cover such as a dryer vent cover on the side of a house, (not illustrated) or other suitable structure over air outlet openings 70. The purpose for air intake openings 65 and air outlet openings 70 is discussed below with reference to FIG. 8 and first, second, and third airspaces 205, 220, and 230.

A cross-section of a preferred ruggedized display panel 40 according to one embodiment is illustrated in FIG. 3. Preferably, a weatherized, or environmentally sealed arrangement is used for a ruggedized display panel, such as display panel 40. A weatherized, or environmentally sealed, arrangement means that a display panel includes protective elements capable of withstanding exposure to an outside environment including fluctuating temperatures, moisture in the form of rain, snow, sleet, hail, and humidity, singularly or in any combination, and radiation from the sun without degrading, or substantially degrading, the display panel's ability to display electronic images.

A preferred ruggedized display panel 40 includes multiple layers which are described with reference to a front (facing a viewer of the display device 5) and a rear (facing backlight housing 15). A front optically transparent plate 75 permits visible light (generally in the range of 400 nm to 700 nm) to pass therethrough. Other wavelengths, such as IR (generally wavelengths above 700 nm to approximately 3,000 nm) and UV (generally wavelengths below 400 nm to approximately 10 nm) may also pass through front optically transparent plate 75. Front optically transparent plate 75 is preferably 2 to 10 millimeters (“mm”) thick and made from non-quartz glass, such as silica glass, but may be made from other suitable materials, including polymers, that permit visible light to pass therethrough. Front optically transparent plate 75 serves as a durable protective barrier between the outside environment and the operable components of ruggedized display panel 40. As discussed below, front optically transparent plate 75 cooperates with a gasket (175 FIG. 7), another gasket (190 FIG. 3), and panel housing 10 to further help protect the operable components of ruggedized display panel 40 from the outside environment.

When the front optically transparent plate 75 is made from non-quartz glass, the front optically transparent plate 75 blocks some ultra-violet (“UV”) radiation, principally with a wavelength of 320 nm and shorter, from reaching the operable portions of ruggedized display panel 40. Optionally, a UV reflecting layer (not illustrated) may be included on the front or rear surface of front optically transparent plate 75. For example, a UV reflecting layer on a non-quartz glass plate preferably reflects UV radiation with wavelengths between 400 nm and 320 nm to prevent them from reaching the operable portion of the ruggedized display panel 40.

The front surface of front optically transparent plate 75 is preferably not coated with an anti-reflective coating. The present inventors have realized that anti-reflective coatings tend to trap cleaning agents, such as solvents, commonly used to clean outdoor display devices, such as display device 5. When cleaning agents become trapped by the anti-reflective coating, smudges, smears, and other obstructions are commonly created that make viewing the display device difficult. Therefore, the present inventors prefer to micro-abrade, for example, by chemically etching the front surface of front optically transparent plate 75, so that the front surface scatters outside visible light to sufficiently break up or blur reflected images. Scattering reflected visible light helps prevent a reflected image from obscuring a projected image. Such scattering helps improve readability of the display device 5 under relatively high ambient light conditions or when a viewer is wearing white or other highly reflective clothing.

An IR reflective layer 80 is preferably included on the front optically transparent plate 75. IR reflective layer 80 is deposited onto the front or rear surface of the front optically transparent plate 75, preferably the rear. A suitable IR reflective layer 80 includes IR Blocker™ made by JDS Uniphase of Santa Rosa, Calif., vacuum deposited by e-beam evaporation on optically transparent plate 75 to a thickness of about 1 μm to about 5 μm. Other suitable materials may be used as well as other thin film deposition methods. Alternately, IR reflective layer 80 may be deposited on a substrate which is subsequently applied to front optically transparent plate 75.

IR reflective layer 80 is preferably included to help reduce heating of the display panel 90 by external radiation sources, such as the sun. Because IR radiation commonly comprises over half of the solar load, IR radiation can impose a significant solar load that heats outdoor devices such as display device 5. IR reflective layer 80 reflects some, or a majority, of the IR radiation before the IR radiation reaches the AMLCD panel 90 within the ruggedized display panel 40 to help prevent IR radiation from heating the AMLCD panel 90. Preferably, display device 5 operates in any full sun environment, including an environment including solar loads of approximately 1150 watts per square meter and ambient temperatures of approximately 50° C. With the addition of heaters (not illustrated), display device 5 preferably operates in ambient temperatures in a range of approximately −20° C. to 50° C.

Preferably, IR reflective layer 80 is terminated with an interface layer having an index of refraction to optically match, or substantially match, the index of refraction of an optical adhesive layer 85 that is placed over IR reflective layer 80. By matching, or substantially matching, the index of refraction of IR reflective layer 80 to the index of refraction of optical adhesive layer 85, reflection of visible light occurring at the boundary between IR reflective layer 80 and optical adhesive layer 85 is reduced. Optical adhesive layer 85 is preferably made from a two-part optically clear silicone and elastomer, such as commercially available optical adhesives manufactured by General Electric Company of Fairfield, Conn. Preferably, the optical adhesive 85 is relatively soft, for example with a Durometer hardness in the range of approximately 25 Shore A to approximately 40 Shore A. Other suitable optical adhesive materials having a similar or a different hardness, including thermally activated urethane or epoxy, light activated silicone and elastomer, urethane, or epoxy, may be used. When a two-part clear silicone and elastomer optical adhesive is used, the IR reflective layer 80 preferably terminates with an index of refraction in the range of 1.44 to 1.5.

In a preferred method for bonding front optically transparent plate 75 to the AMLCD panel 90, front optically transparent plate 75 is placed in a mold (not illustrated). Optical adhesive layer 85 is preferably poured over front optically transparent plate 75 and IR reflective layer 80, and is retained in place by the mold. AMLCD panel 90 is pressed into optical adhesive layer 85, preferably to remove all, or substantially all, air bubbles or other trapped air. Optical adhesive layer 85 is then thermally cured, for example at 45° C. for two hours. Alternately, AMLCD panel 90 may be placed in a mold and optical adhesive layer 85 poured over the AMLCD panel 90. Front optically transparent plate 75 is then pressed into the optical adhesive layer 85 before thermal curing. Optical adhesive layer 85 is preferably in the range of about 1,500 μm to 2,500 μm thick when cured.

When front optically transparent plate 75 and the AMLCD panel 90 are pressed together with the optical adhesive layer 85 in between, optical adhesive material extends beyond the boundary of the AMLCD panel 90. Preferably, the optical adhesive layer 85 is thermally cured, and the cured optical adhesive material that extends beyond the border of the AMLCD 90 is trimmed away. Alternately, the cured optical adhesive material that extends beyond the border of the AMLCD 90 may be left in place, especially if the bonding material 155 used to encase electronics associated with the AMLCD panel 90, as described below, has an index of refraction that substantially matches the index of refraction of the cured optical adhesive layer 85.

A display panel may include several components. In a preferred embodiment, display panel is an AMLCD panel 90 that includes a front polarizer 95, a front glass substrate 100, a rear glass substrate 105, and a rear polarizer 110. A liquid crystal is contained between the front glass substrate 100 and rear glass substrate 105. Thus, in a preferred embodiment, front optically transparent plate 75 is preferably bonded to front polarizer 95 of display panel 90 such that the optical adhesive layer 85 protects front polarizer 95 from the outside environment.

A dual brightness enhancing film 115 is preferably placed adjacent the rear polarizer 110. Dual brightness enhancing film 115 is preferably made of Vikuiti,™ manufactured by 3M of St. Paul, Minn., and may be laminated to rear polarizer 110, or simply placed next to rear polarizer 110 without any adhesive in between.

A rear optically transparent plate 120 is bonded to rear glass substrate 105 using an optical adhesive layer 125 that is preferably the same as, or similar to, optical adhesive layer 85. The front and rear optically transparent plates 75 and 120 and bonding adhesives thus preferably cover polarizers 95 and 110 to provide protection from humidity and other environmental conditions that can adversely affect the polarizers 95 and 110. Rear optically transparent plate 120 is preferably thinner than front optically transparent plate 75, for example, within a range of 1 to 5 mm thick. Preferably, optically transparent plates 120 and 75 are made from the same material.

Rear optically transparent plate 120 preferably has a slightly lesser width, that is the distance extending between the right-side frame 20 and the left-side frame 25 (FIG. 1), than front optically transparent plate 75 as illustrated in FIG. 3. Likewise, rear optically transparent plate 120 preferably has a slightly lesser height, that is the distance extending between the top frame 30 and the bottom frame 35 (FIG. 1), than front optically transparent plate 75. One reason for making the rear optically transparent plate 120 smaller than the front optically transparent plate 75 is to facilitate potting various electronics associated with the display panel 90 between the rear optically transparent plate 120 and the front optically transparent plate 75. Alternately, rear optically transparent plate 120 may be the same size as, or larger than, front optically transparent plate 75.

As illustrated in FIG. 4B, rear optically transparent plate 120 is optional. In one embodiment, a driver electronics cover 122 is included when a ruggedized display panel 41, similar to ruggedized display panel 40, is constructed. Cover 122 preferably extends around the periphery of the ruggedized display panel 41 and is preferably made from a rigid material such as high density polyethylene, other suitable polymer, glass, or other suitable material. Cover 122 serves as a mechanical interface for the rear of ruggedized display panel 41, preferably to resist wear and tear, including material break-down, of the bonding material 155, especially when the bonding material 155 is relatively soft when cured. When a cover 122 is included in ruggedized display panel 41, the bonding material 155 preferably has an inner terminal edge 123 that does not extend past the wall 186 of extruded portion 180. Thus, the bonding material 155 preferably does not extend over a portion of the AMLCD panel 90 that is operative to display viewable images. Alternately, rear optically transparent plate 120 and cover 122 may be omitted (not illustrated).

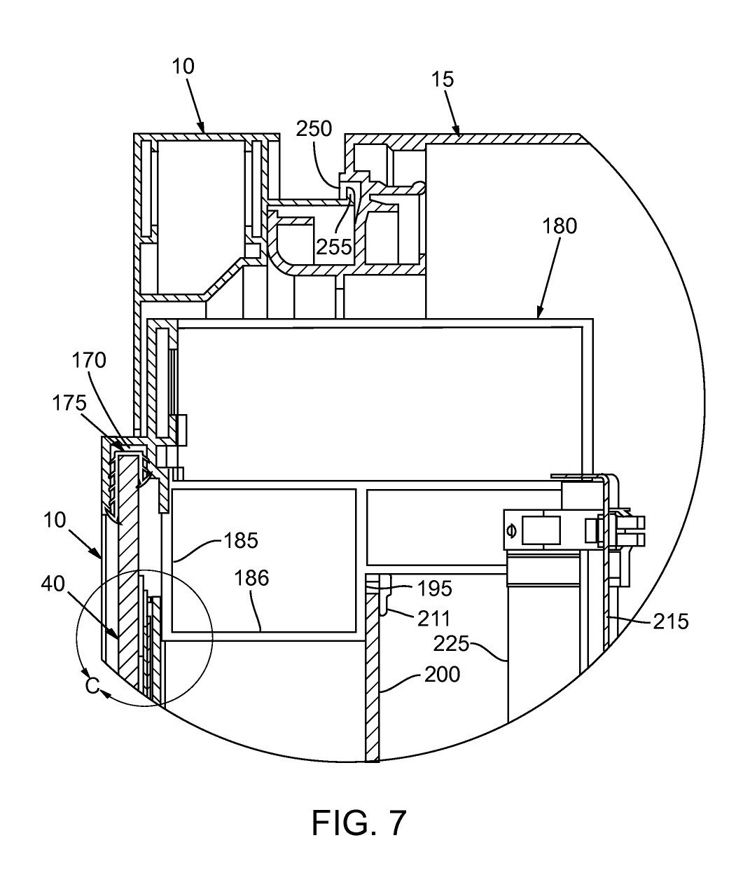

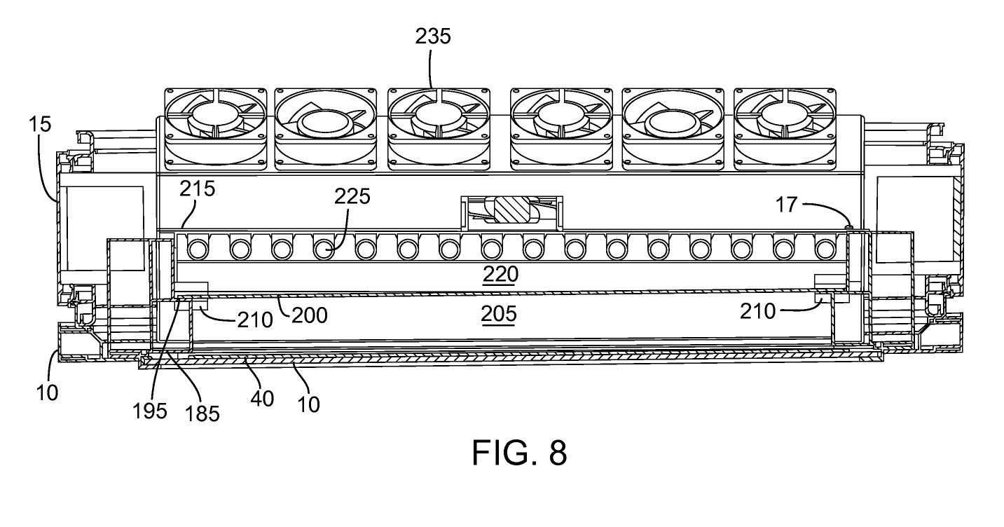

FIG. 5 illustrates an AMLDC panel 90 before it is optically bonded between front optically transparent plate 75 and rear optically transparent plate 120. In a conventional electronic display using an AMLCD panel 90, illustrated in FIG. 6, the AMLCD panel 90 is located in close proximity to a backlight 125 to produce an electronic display that is as thin as possible. An active matrix of thin film transistors (“TFT”) is contained in the AMLCD panel 90 on the inner surface of one or both of the glass substrates 100, 105 of the panel 90. The active matrix is controlled to manipulate liquid crystal material contained between glass substrates 100, 105 to present images and video on the AMLCD panel 90. TFTs are the underlying elements of pixels that permit light (from the backlight) to shine through the AMLCD panel 90, typically in red, blue, and green for color displays.

Two common TFT control elements associated with the AMLCD panel 90 are the column drivers 130 and row drivers 135 which are commonly attached to a flexible circuit 140. Each flexible circuit 140 attaches to hundreds, or thousands, of conductive leads extending from the TFTs in the active matrix. The column drivers 130 and row drivers 135 receive electrical control signals from control driver electronics connected to the flex circuits 140, and in response, send electric currents over the conductive leads connected to each individual TFT to drive TFTs to activate or deactivate depending on where, and which color, light should shine through AMLCD panel 90. The column drivers 130 and row drivers 135 are essentially complex, intelligent on/off switches for the TFTs.

The flexible circuits 140 are commonly attached to other electronics associated with the AMLCD panel 90 such as a column driver board 145 or a row driver board 150. Column driver boards 145 and row driver boards 150 provide more complex logic circuits that receive video or image signals from a processor and route or create on/off commands for various TFTs to multiple column drivers 130 and row drivers 135. In other words, column driver boards 145 and row driver boards 150 receive video or image signals, and based on such signals decide which particular column driver 130 or row driver 135 should switch on or off which particular TFTs.

The present inventors have recognized that one drawback to using flex circuits 140 bearing column drivers 130 and row drivers 135 to connect between TFT leads and column driver boards 145 and row driver boards 150 is that the connections are fragile and need to be protected from environmental elements such as particles and water and against mechanical stresses, such as those induced during manufacture or transport, that could cause any of the electronic elements to become unattached. For indoor electronic displays, such protection is commonly provided by securing the flex circuits 140, column drivers 130, row drivers 135, column driver boards 145 and row driver boards 150 to the backlight 125 (FIG. 6) and by providing a protective housing (not illustrated) around the AMLCD panel 90 and backlight 125. Because of the relatively controlled environment encountered indoors, such measures provide adequate protection for electronic displays.

The present inventors have recognized that protective measures adequate for indoor environments are not adequate for outdoor environments. Hence, the AMLCD panel 90 is preferably contained between a front optically transparent plate 75 and a rear optically transparent plate 120 as described above.

The present inventors have also recognized that electronic components associated with an electronic display panel such as flex circuits 140, column drivers 130, row drivers 135, and, in some instances, column driver boards 145 and row driver boards 150, can be protected by encasing them in a resin or other suitable material between the same front optically transparent plate 75 and rear optically transparent plate 120 that provide environmental protection for the AMLCD panel 90. Preferably, flex circuits 140, column driver boards 145, and row driver boards 150 are arranged to extend substantially in the same plane as the rear glass substrate 105 and between the front optically transparent plate 75 and the rear optically transparent plate 120 as illustrated in FIGS. 3 and 4A.

The flex circuits 140, column drivers 130, row drivers 135, column driver boards 145 and row driver boards 150 are preferably potted to the display panel 90 by filling, or substantially filling, the space between the front optically transparent plate 75 and the rear optically transparent plate 120 with a bonding material 155, such as the same thermally cured two-part silicone and elastomeric material that is used to bond the front optically transparent plate 75 to the AMLCD panel 90. Alternately, the bonding material 155 may include a resin, sealant, other optical adhesive, or other suitable material.

In one embodiment, sufficient bonding material 155 is used to encapsulate the flex circuits 140, column drivers 130, and row drivers 135, but not the column driver boards 145 or row driver boards 150. In another embodiment, sufficient bonding material 155 is used to encapsulate the flex circuits 140, column drivers 130, row drivers 135, column driver boards 145 and row driver boards 150, leaving the ribbon cables 160 (FIG. 5) accessible to provide communication between the AMLCD panel 90 and external electronics, such as a video driver. Alternately, the AMLCD display panel 90 may communicate with external electronics, such as a video driver, via wireless or optical systems. For example, a wireless transceiver may be operatively connected to the ribbon cables 160, or the ribbon cables 160 may be replaced by an optical cable. Alternately, wireless transceivers may be integrated into the electronics associated with the AMLCD panel 90, on the driver boards 145 and 150, for example. By encapsulating, or substantially encapsulating, the flex circuits 140, column drivers 130, row drivers 135, column driver boards 145 and row driver boards 150 in a bonding material 155 environmental protection is provided for the flex circuits 140, column drivers 130, row drivers 135, column driver boards 145 and row driver boards 150.

By bonding the flex circuits 140, column drivers 130, row drivers 135, column driver boards 145 and row driver boards 150 to the front optically transparent plate 75 and, in some instances, between the front optically transparent plate 75 and the rear optically transparent plate 120, protection against mechanical shocks and stresses is provided to resist separation of the electronic components. Thus, in some embodiments bonding the front optically transparent plate 75 and the rear optically transparent plate 120 to the AMLCD panel 90 and potting the electronic components associated with the AMLCD panel 90 between the front optically transparent plate 75 and the rear optically transparent plate 120 provides environmental and mechanical protection independent of any housing. Potting the flex circuits 140, column drivers 130, row drivers 135, column driver boards 145 and row driver boards 150 to or between the front optically transparent plate 75 and the rear optically transparent plate 120 also eliminates the need to use a backlight structure, such as backlight 125 (FIG. 6), to support and protect the electronics associated with the AMLCD panel 90. A ruggedized display panel 40 that can be physically separated from a backlight is thus created.

Advantageously, using a relatively soft bonding material 155 and a relatively soft optical adhesive layer 85 provides shock absorbing and distribution capabilities such that the magnitude of mechanical shocks and stresses imparted to components of the display device 5, including components of the ruggedized display panel 40, are lessened before reaching the AMLCD panel 90.

Ruggedized display panel 40 is retained in panel housing 10. In the preferred embodiment, each of the right-side frame 20, left-side frame 25, top frame 30, and bottom frame 35 include a channel 170 sized to receive and retain a gasket 175 and the front optically transparent plate 75 as illustrated in FIG. 7. Channels 170 preferably extend along the entire length of each of the right-side frame 20, left-side frame 25, top frame 30, and bottom frame 35. Gasket 175 is preferably a single piece of material, such as neoprene, natural rubber, or other suitable material, but may be made from more than one piece. Gasket 175 is preferably sized to provide a sufficient seal that substantially prevents liquids and particulate matter from entering the panel housing 10 through the channels 170, but does not need to prevent entrance of all particulate matter or liquids.

In each of the right-side frame 20, left-side frame 25, top frame 30, and bottom frame 35 an extruded portion 180 includes a wall 185 that is spaced a sufficient distance from channel 170 to provide a rest for rear optically transparent plate 120. Preferably, a gasket 190 (FIG. 3) is placed between wall 185 and rear optically transparent plate 120 to provide a cushion and to act as a pseudo spring member that cooperates with gasket 175 to retain the ruggedized display panel 40 in place in the panel housing 10. In a preferred embodiment, extruded portion 180 extends along the length of the right-side frame 20 and the left-side frame 25, but only extends a distance from the ends of the top frame 30 and the bottom frame 35 sufficient to reach the edge of a lamp support frame (215 FIG. 8) as best illustrated in FIG. 8.

A second wall 195 provides a rest for diffuser 200 and keeps diffuser 200 spaced apart from ruggedized display panel 40. Diffuser 200 is preferably a material such as a sheet of acrylic plastic or other suitable light spreading or translucent polymer. However, any suitable diffuser material may be used.

In a preferred embodiment, the distance from the rear surface of rear optically transparent plate 120 to the front surface of diffuser 200 is 49 mm, but other distances may be used. The space between ruggedized display panel 40 and diffuser 200 creates a first airspace 205 (FIG. 9) which is described in more detail below.

Diffuser 200 is preferably removeably held in place and is not bonded to second wall 195. In a preferred embodiment, U-blocks 210 support diffuser 200 in place and pivoting tabs (211, FIG. 7) help retain diffuser 200 in place, for example by pinching the top corners of diffuser 200 to wall 195. Diffuser 200 is therefore preferably retained in place such that no tools are needed to remove diffuser 200 from panel housing 10 for cleaning or repair of rear optically transparent plate 120. In alternate embodiments (not illustrated), diffuser 200 may be bonded to second wall 195, or retained by screws or other suitable fasteners that require tools to loosen and tighten.

As illustrated in FIGS. 7-9, a lamp support frame 215 is retained in backlight housing 15. A second airspace 220 is substantially defined between diffuser 200 and lamp support frame 215. Lamps 225 are preferably retained in the second airspace 220, that is, air moving through airspace 220 preferably directly contacts lamps 225. Lamps 225 are preferably HCFLs, and preferably lower cost lamps that have a lower mean time between failure are used. Such lower cost HCFLs with a lower mean time between failure may be used because the display device 5 is easily opened in the field, preferably without requiring the use of tools, and lamps 225 are easily replaced in the field, also preferably without requiring the use of tools. In one embodiment an internal photo sensor is placed in the backlight housing 15 or the panel housing 10 and communicates over a communication network to indicate lamp 225 failures to let a technician know to go replace lamps 225.

Many current AMLCD electronic displays use CCFLs for a backlight because CCFLs generate relatively little heat compared to HCFLs, thus permitting a relatively thin electronic display by placing the backlight proximate the display panel without excessively heating the display panel. The present inventors have recognized that CCFLs are more expensive and delicate than HCFLs, CCFLs tend to burn out sooner, and that CCFLs require protection from particulate matter because CCFLs generate electric fields that attract particulate matter. If CCFLs are not housed in a relatively sealed housing, CCFLs, and potentially the entire backlight cavity, become coated with particulate matter. The present inventors have also recognized that HCFLs, while generating more heat than CCFLs, do not attract relatively large quantities of particulate matter. By making panel housing 10 easily openable with respect to backlight housing 15, for example, by unlatching a mechanical latch and swinging panel housing 10 away from backlight housing 15 on hinge 17, detaching panel housing 10 from backlight housing 15, or other suitable arrangement, the interior of the panel housing 10 and backlight housing 15 may easily be cleaned, thus reducing the need to seal the interiors of the housings 10 and 15 from the outside environment.

One advantage of embodiments including easily opening housings is that the backlight, diffuser, and display panel are preferably readily cleaned. Thus, air passages, described in detail below, preferably communicate with air outside the housing to provide cooling air for the display panel, backlight, and other electronics contained in the housing without worrying that too much dust or dirt will become trapped in the housing.

An exemplary embodiment that may readily be cleaned is illustrated in FIG. 8A. Preferably, a front housing 810 hinges or pivots open with respect to a rear housing 815 to provide access to the backlight and diffuser 8200. Preferably, opening housing 810, 815 provides direct access to lamps 8225, which may be dusted or wiped down to remove particulate matter. Any non-working, or partially working, lamps 8225 may simply be removed and replaced. Opening housing 810, 815 also preferably provides direct access to the backside of diffuser 8200, which may be wiped or otherwise cleaned. Hand operable holders, such as pivoting tabs 211 (FIG. 7) or other suitable holders, preferably allow a technician to remove diffuser 8200 without tools. The front side of diffuser 8200 may be wiped or cleaned, as well as the back side of the display panel (not illustrated in FIG. 8, but similar to display panel 90). Other suitable arrangements for opening a housing and cleaning the interior components, including electronics behind the backlight, may be used. For example, a portion of the rear housing 815 may hinge or pivot open to permit cleaning of electronics housed therein.

In a preferred embodiment, spacing the lamps 225 away from ruggedized display panel 40, and interposing the first and second airspaces 205 and 220 between lamps 225 and ruggedized display panel 40, preferably thermally separates the lamps 225 from ruggedized display panel 40. Providing one or more airspaces helps thermally separate, or isolate, lamps 225 from ruggedized display panel 40 by changing the mode of heat transfer from primarily conduction (as when a backlight is proximate a display) to primarily convection. Convection is a less efficient mode of heat transfer, and thus helps thermally separate, or isolate, lamps 225 from ruggedized display 40. Additionally, air flowing through the first and second airspaces 205 and 220 moves heat from the lamps 225, for example, to the top of backlight housing 15 and out through air outlet openings 70 as described below.

FIG. 9 illustrates a cross sectional side view of a preferred embodiment. First airspace 205, second airspace 220, and third airspace 230 are used to convey air blown by fans 235. Because the panel housing 10 and the backlight housing 15 are easily opened and cleaned, dust and other contaminants introduced through a fan system, such as fans 235, are a lesser concern regarding degrading performance of the display device 5. In the preferred embodiment, two of the fans 235 are associated with ducting that directs air blown by the fans 235 through the first airspace 205 as illustrated in FIG. 9. Two of the fans 235 are associated with ducting that directs air blown by the fans 235 through the second airspace 220. The remaining two fans 235 are associated with ducting that directs air blown by the fans 235 through the third airspace 230. Other suitable fan and duct arrangements may be used, for example, a fan system, which includes one or more fans, may be used with appropriate ducting to direct outside air into one or more of the first airspace 205, second airspace 220, and third airspace 230. In some environments, such as Northern or Southern environments with relatively cool summer climates, it may be possible to have embodiments that do not use a fan system.

In other embodiments, a single airspace, such as airspace 220, is provided between a backlight, such as lamps 225, and a diffuser, such as diffuser 200. Air is preferably moved through the single airspace, for example, as described below, to remove heat from the backlight without such heat significantly reaching a display panel, such as display panel 90. Alternate embodiments include only an airspace between the diffuser and the display panel, and air is preferably moved through the airspace between the diffuser and the display panel. In yet other embodiments a first airspace between the display panel and the diffuser and a second airspace between the diffuser and the backlight are included. Air may be moved through either or both of the first and second airspaces.

Fans 235 operate to draw air from outside backlight housing 15 through the fans 235 and through the air intake openings 65 (FIG. 2). The outside air moves through the first, second, and third airspaces 205, 220, and 230. As air moves through the first airspace 205, the air is heated primarily by the ruggedized display panel 40, and thus the moving air helps remove heat from the ruggedized display panel 40. As air moves through the second airspace 220, the air is heated primarily by the lamps 225, and thus the moving air helps remove heat from the lamps 225 without such heat significantly reaching ruggedized display panel 40. As air moves through the third airspace 230, the air is heated primarily by ballast 227 and any other electric components, such as video driver 240, contained within the third airspace 230. Thus, the moving air helps remove heat from electric components without such heat significantly reaching ruggedized display panel 40. The heated air moving through the first, second, and third airspaces 205, 220, and 230 exits panel housing 10 and backlight housing 15 via air outlet openings 70 to transfer heat from the display panel 40, lamps 225, and electronics outside the housing 10, 15. The positive pressure created by the air moving through panel housing 10 and backlight housing 15 preferably substantially prevents particulate matter, insects, liquids and other foreign matter from entering the panel housing 10 and backlight housing 15 through the air outlet openings 70.

Backlight housing 15 preferably includes an outer lip 245 sized to mate with a display casing (not illustrated). For example, backlight housing 15 and outer lip 245 may be sized to fit within a typical casing for a Quick Service Restaurant (“QSR”) light box and mate with a supporting structure within the QSR light box to hold the display device 5 in place. A display casing thus provides at least some protection from environmental elements for fans 235 and other components mounted at the rear of backlight housing 15. Alternately, backlight housing 15 may cover fans 235 and the display device 5 may be mounted on a post or by the panel housing 10.

Panel housing 10 preferably includes a circumferential gasket 250 (FIG. 7). In the preferred embodiment circumferential gasket 250 is retained on a lip 255. Circumferential gasket 250 is preferably sized to interact with both the panel housing 10 and the backlight housing 15 to substantially prevent liquids, particulate matter, and light from entering the display device 5 through the interface between the panel housing 10 and the backlight housing 15. However, circumferential gasket 250 preferably does not provide a fluid tight or hermetic seal between the panel housing 10 and the backlight housing 15.

FIG. 9A illustrates a cross sectional side view of another preferred embodiment. First airspace 205A, second airspace 220A, and third airspace 230A are used to convey air blown by fans 235A. Because the panel housing 10A and the backlight housing 15A are easily opened and cleaned, dust and other contaminants introduced through fans 235A are a lesser concern regarding degrading performance of the display device 5A. In the preferred embodiment, the fans 235A are associated with ducting that directs outside air 11A from outside the panel housing 10A and the backlight housing 15A blown by the fans 235A through the first airspace 205A as illustrated in FIG. 9A. Outside air 11A preferably enters the panel housing 10A and the backlight housing 15A via air inlet 66A and through fans 235A. Outside air 11A may also enter the panel housing 10A and the backlight housing 15A via additional air intake openings, such as air intake openings 65 described above, or through seams and openings between the panel housing 10A and the backlight housing 15A. Other suitable fan and duct arrangements may be used.

First airspace 205A, second airspace 220A, and third airspace 230A preferably communicate with one another to permit outside air 11A to conduct heat away from various components of the display 5A. For example, outside air 11A preferably follows a serpentine path that sequentially contacts flowing outside air 11A with display panel 40A, lamps 225A, and electronic devices such as ballast 227A. Display panel 40A, lamps 225A, and electronic devices such as ballast 227A preferably either form a boundary or wall of an airspace 205A, 220A, or 230A or are located within an airspace 205A, 220A, or 230A.

In a preferred arrangement, outside air 11A is directed by fans 235A into first airspace 205A such that outside air 11A flows through first airspace 205A in an upward direction, in other words, in a direction opposite the force of gravity. First airspace 205A preferably communicates with second airspace 220A at an upper end or portion of first and second airspaces 205A and 220A. Outside air 11A is preferably redirected from first airspace 205A to second airspace 220A, for example, as illustrated at 12A. Preferably, outside air 11A moves past or over display panel 40A, thus removing heat from display panel 40A via conduction, convection, or both. After moving through the first airspace 205A, outside air 11A is preferably warmer than it was before entering the panel housing 10A and the backlight housing 15A because of heat transferred from the display panel 40A to the outside air 11A.

Outside air 11A is preferably directed from the first airspace 205A to the second airspace 220A to move through the second airspace 220A. Preferably, outside air 11A flows through the second airspace 220A in a downward direction, in other words, in the direction of the force of gravity. As the outside air 11A moves through the second airspace 220A, the outside air 11A preferably moves past or over the lamps 225A, thus removing heat from the lamps 225A via conduction, convection, or both, without such heat removed from the lamps 225A significantly reaching ruggedized display panel 40A. As discussed above, outside air 11A is warmed by removing heat from display panel 40A. Preferably, outside air 11A that has been warmed by display panel 40A causes less of a temperature gradient, or differential, along the length of lamps 225A when compared to a temperature gradient, or differential, caused by outside air, such as outside air introduced directly from outside a housing, such as panel housing 10 and backlight housing 15 (FIG. 9), into contact with lamps, such as lamps 225 (FIG. 9). Causing, or inducing, such a lesser temperature gradient, or differential, along the length of lamps, such as hot cathode lamps 225A, preferably enhances the performance of such lamps. For example, a lesser temperature gradient along the length of a hot cathode lamp preferably provides a relatively uniform light, in terms of lumens, wavelength (color), or both, emitted from along such a lamp, a longer useful life, or other suitable advantages.

Outside air 11A is preferably directed from the second airspace 220A to the third airspace 230A to move through the third airspace 230A, for example, as illustrated at 13A. Preferably, outside air 11A flows through the third airspace 230A in an upward direction, in other words, in the direction opposite the force of gravity. As air moves through the third airspace 230A, the air is heated primarily by ballast 227A and any other electric components, such as video driver 240A, contained within the third airspace 230A. Alternately, one or more of fans 235A may be arranged to direct outside air 11A directly from outside housing 10A, 15A into the third airspace 230A to co-mingle with air that previously moved through the first and second airspaces 205A and 220A. Thus, the moving air helps remove heat from electric components without such heat significantly reaching ruggedized display panel 40A. The heated air moving through the first, second, and third airspaces 205A, 220A, and 230A preferably exits panel housing 10A and backlight housing 15A via air exit 71A, for example, as illustrated at 14A. The positive pressure created by the air moving through panel housing 10A and backlight housing 15A preferably substantially prevents particulate matter, insects, liquids and other foreign matter from entering the panel housing 10A and backlight housing 15A through the air exit 71A.

Backlight housing 15A preferably includes a protective backing 246A that includes suitable structure to inhibit liquid, such as rain, from flowing into backlight housing 15A. For example, air inlet 66A and air exit 71A may include louvers as illustrated in FIG. 9A, a slanted rain guard, or other suitable structure. Alternately, backlight housing 15A may include an outer lip sized to fit within a typical casing for a QSR light box and mate with a supporting structure within the QSR light box to hold the display device 5A in place. A protective backing 246A, or a display casing thus provides at least some protection from environmental elements for fans 235A and other components mounted at the rear of backlight housing 15A.

Panel housing 10A preferably includes a circumferential gasket, such as gasket 250 (FIG. 7), retained on a lip, such as lip 255 (FIG. 7). A circumferential gasket is preferably sized to interact with both the panel housing 10A and the backlight housing 15A to inhibit liquids, particulate matter, and light from entering the display device 5A through the interface between the panel housing 10A and the backlight housing 15A. However, a circumferential gasket preferably does not need to provide a fluid tight or hermetic seal between the panel housing 10A and the backlight housing 15A.

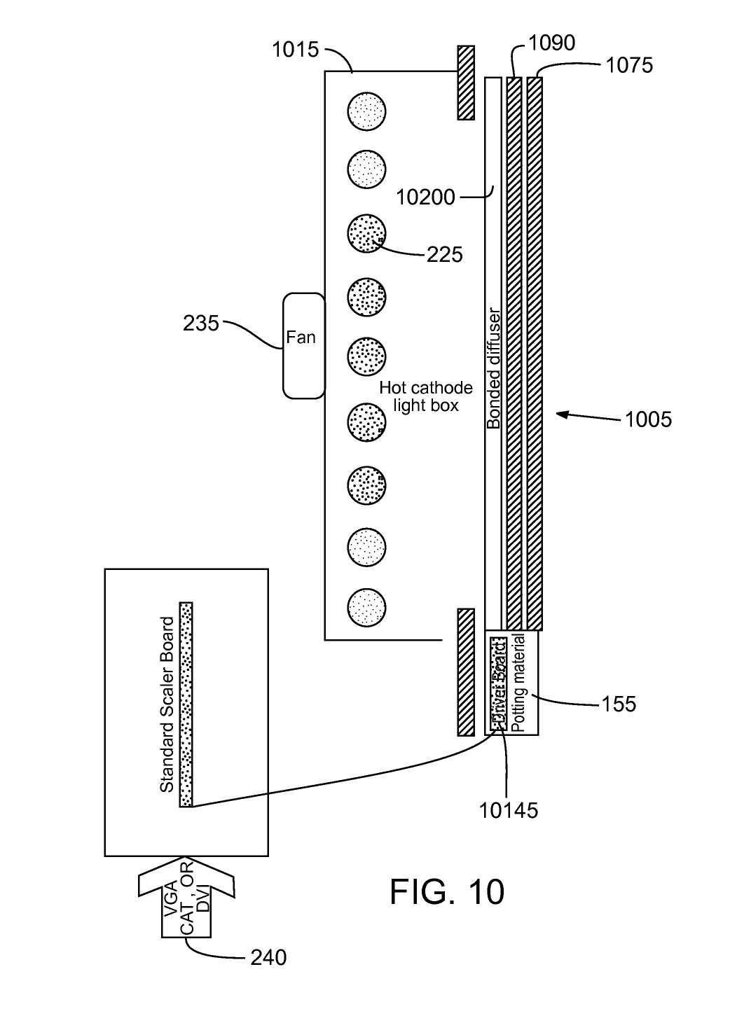

FIG. 10 illustrates a schematic view of an alternate embodiment. A backlight housing 1015 contains lamps 225 that are cooled by a fan 235. An optically transparent plate 1075 is bonded to the front surface of an AMLCD panel 1090. Optically transparent plate 1075 includes an IR reflective coating and optionally includes an anti-reflective coating. A diffuser 10200 is bonded to the rear surface of the AMLCD panel 1090. AMLCD panel electronics 10145 are potted to the combination of the AMLCD panel 1090, optically transparent plate 1075, and diffuser 10200 in a manner similar to what is described above. A panel frame (not illustrated) detachably retains the AMLCD panel electronics 10145, AMLCD panel 1090, optically transparent plate 1075, and diffuser 10200. A video driver 240 is located remotely from the display device 1005 and communicates with the display device 1005 over any suitable connection such as a wired, wireless, or optical connection or network.

It will be obvious to those having skill in the art that many changes may be made to the details of the above-described embodiments without departing from the underlying principles of the invention. The scope of the present invention should, therefore, not be limited to the above specific examples.

1. An outdoor electronic display comprising:
a housing including an openable and closeable portion to access an interior of the housing;
a weatherized electronic display panel retained in the housing;
a backlight retained in the housing;
a diffuser positioned in the housing between the weatherized electronic display panel and the backlight;
a first airspace defined between the diffuser and the backlight; and
a fan system attached to the housing, wherein the fan system is configured to move air from outside the housing through an air inlet, through the first airspace, and back outside the housing through an air outlet to transfer heat from at least the backlight outside the housing.

2. The outdoor electronic display of claim 1, further comprising:
a second airspace defined between the display panel and the diffuser
wherein the fan system is further configured to move air from outside the housing through the air inlet, through the second airspace, and back outside the housing through the air outlet to transfer heat from at least the display panel outside the housing.

3. The outdoor electronic display of claim 1, wherein:
the air inlet is positioned proximate a bottom of the housing to inhibit liquid that enters the air inlet from reaching the electronic display panel or other electronics located in the housing; and
the fan system is positioned proximate the bottom of the housing to inhibit liquid that enters the fan system from reaching the electronic display panel or other electronics located in the housing.

4. The outdoor electronic display of claim 2, wherein the second airspace communicates with the first airspace and the fan system is configured to sequentially move air from outside the housing into and through the second airspace, from the second airspace into and through the first airspace, and from the first airspace out substantially through the air outlet.

5. The outdoor electronic display of claim 2, further comprising:
a second fan system;
wherein the first fan system is configured to move air from outside the housing through the first airspace and out through the air outlet and the second fan system is configured to move air from outside the housing through the second airspace and out through the air outlet.

6. The outdoor electronic display of claim 2, wherein the second airspace extends substantially over the length and width of the electronic display panel and the first airspace is substantially parallel with the second airspace.

7. The outdoor electronic display of claim 2, further comprising:
a third airspace extending between the backlight and the back portion of the housing;
wherein the fan system is further configured to move air from outside the housing through the air inlet, through the third airspace, and back outside the housing through the air outlet.

8. The outdoor electronic display of claim 7, wherein:
the second airspace communicates with the first airspace and the first airspace communicates with the third airspace; and
the fan system is configured to move air sequentially from outside the housing substantially through the air inlet and in a serpentine path (a) from the air inlet into and through the second airspace, (b) from the second airspace into and through the first airspace, (c) from the first airspace into and through the third airspace, and (d) from the third airspace back outside the housing substantially through the air outlet.

9. The outdoor electronic display of claim 1, further comprising:
a first mechanical fastener retaining the diffuser in the housing, wherein the first mechanical fastener is operable by human hands without tools to release the diffuser from the housing; and
a second mechanical fastener holding the openable and closeable portion of the housing closed with respect to a remainder of the housing, wherein the second mechanical fastener is operable by human hands without tools to open the housing.

10. The outdoor electronic display of claim 9, further comprising an electrical interlock activated by releasing the second mechanical fastener to open the housing, wherein the electrical interlock is configured to prevent electrical power from being supplied to the electronic display when the housing is opened.

11. The outdoor electronic display of claim 1, further comprising a hinge pivotally securing the openable and closeable portion of the housing to a remainder of the housing.

12. The outdoor electronic display of claim 11, wherein:
the openable and closeable portion of the housing retains the weatherized display panel and the diffuser; and
the remainder of the housing retains the backlight.

13. The outdoor electronic display of claim 1, further comprising a sealing element between the openable and closeable portion of the housing and a remaining portion of the housing, wherein the sealing element is liquid-leak-resistant.

14. The outdoor electronic display of claim 1, further comprising a photo sensor retained in the housing, wherein the photo sensor communicates over a network to indicate backlight failures.

15. The outdoor electronic display of claim 1, wherein the weatherized electronic display panel includes a front optically transparent plate optically bonded to a viewer side of the electronic display panel and a bonding material encasing a periphery of the electronic display panel and encasing electronics associated with the electronic display panel.

16. The outdoor electronic display of claim 15, further comprising an electronics cover substantially overlying the electronics associated with the electronic display panel and secured in place by the bonding material;
wherein the electronics cover substantially extends over a periphery of the electronic display panel and the electronics associated with the electronic display panel are located between the electronics cover and the front optically transparent plate.

17. The outdoor electronic display of claim 15, further comprising a back optically transparent plate optically bonded to a non-viewer side of the electronic display panel;
wherein the back optically transparent plate substantially overlies the electronic display panel and the electronics associated with the electronic display panel are located between the back optically transparent plate and the front optically transparent plate.

18. An outdoor electronic display device comprising:
a housing means for sheltering an electronic display panel and its associated electronics;
a weatherized electronic display panel means for showing images;
a backlight means for providing light to a non-viewer side of the weatherized display panel means;
a diffuser means for diffusing light from the backlight means before said light reaches the weatherized display panel means;
a cooling passage means including a first portion located between the electronic display panel means and the diffuser means and a second portion located between the diffuser means and the backlight means for guiding flowing air through the housing means; and
an airflow means for flowing air from outside the housing means through the cooling passage means and back outside the housing means.

19. An outdoor electronic display device comprising:
a housing;
a backlight in the housing;
an electronic display panel retained in the housing having a viewer side and an opposing non-viewer side;
a front optically transparent plate optically bonded to the viewer side of the electronic display panel by an optical adhesive layer, wherein the front optically transparent plate extends beyond at least one edge of the electronic display panel; and
a bonding material encasing a periphery of the electronic display panel and encasing electronics associated with the electronic display panel to seal the electronics from an outside environment and to mechanically attach the electronics to the front optically transparent plate to provide stability and support for the electronics.

20. The outdoor electronic display of claim 19, further comprising an electronics cover substantially overlying the electronics associated with the electronic display panel and secured in place by the bonding material;
wherein the electronics cover substantially extends over a periphery of the electronic display panel and the electronics associated with the electronic display panel are mechanically attached to the electronics cover and the front optically transparent plate via the bonding material.

21. The outdoor electronic display of claim 19, further comprising a back optically transparent plate optically bonded to the non-viewer side of the electronic display panel;
wherein the back optically transparent plate substantially overlies the electronic display panel and the electronics associated with the electronic display panel are mechanically attached to the back optically transparent plate and the front optically transparent plate via the bonding material.
